(19) United States
(12) Patent Application Publication
(10) Pub. No.: US 2026/0190418 A1
(43) Pub. Date: Jul. 2, 2026

(54) BACKSIDE CONTACTS FOR IMPROVED SOURCE/DRAIN CONNECTION

(71) Applicant: Intel Corporation, Santa Clara, CA (US)

(72) Inventors: Mauro J. Kobrinsky, Portland, OR (US); Nikhil J. Mehta, Portland, OR (US); Atul Madhavan, Portland, OR (US); Shu Zhou, Portland, OR (US); Umang Desai, Portland, OR (US); Nicholas J. Kybert, Portland, OR (US); Joseph D'Silva, Hillsboro, OR (US); Shaun Mills, Hillsboro, OR (US); Ehren Mannebach, Beaverton, OR (US)

(73) Assignee: Intel Corporation, Santa Clara, CA (US)

(21) Appl. No.: 19/002,927

(22) Filed: Dec. 27, 2024

(51) Int. Cl. H10D 64/23; H10D 30/00; H10D 30/47; H10D 84/83

(52) U.S. Cl. CPC H10D 64/251; H10D 30/47; H10D 30/501; H10D 84/832

(57) ABSTRACT

Backside conductive contacts beneath source or drain regions that extend into the source or drain regions are discussed. A semiconductor device includes a gate structure around or otherwise on a semiconductor region that extends from a source or drain region. The substrate beneath the semiconductor device may be removed from the backside to expose a plug of sacrificial material previously formed beneath the source or drain region. The sacrificial plug is removed to form a backside cavity beneath the source or drain region. A dielectric liner is formed in the backside cavity followed by a directional etching process to form a recess through the bottom surface of the source or drain region. The backside cavity and corresponding recess are filled with a conductive material to form the backside contact. The backside contact may contact a frontside contact within the source or drain region.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Due to the small size of the transistor elements, such as the transistor gate, source, or drain, it can be difficult to provide effective contacts while maintaining desired operation speeds and power requirements. Accordingly, there remain a number of non-trivial challenges with respect to forming such high-density semiconductor devices.

### BRIEF DESCRIPTION OF THE DRAWINGS

FIG. 1A is an isometric view of an integrated circuit structure that includes backside contacts extending into the source or drain regions, in accordance with an embodiment of the present disclosure.

FIGS. 1B and 1C are different cross-sectional views of the integrated circuit of FIG. 1A that show the backside contacts extending into the source or drain regions, in accordance with an embodiment of the present disclosure.

FIGS. 2A and 2B are cross-sectional views that illustrate one stage in an example process for forming an integrated circuit configured with backside contacts that extend into the source or drain regions, in accordance with an embodiment of the present disclosure.

FIGS. 3A and 3B are cross-sectional views that illustrate another stage in the example process for forming an integrated circuit configured with backside contacts that extend into the source or drain regions, in accordance with an embodiment of the present disclosure.

FIGS. 4A and 4B are cross-sectional views that illustrate another stage in the example process for forming an integrated circuit configured with backside contacts that extend into the source or drain regions, in accordance with an embodiment of the present disclosure.

FIGS. 5A and 5B are cross-sectional views that illustrate another stage in the example process for forming an integrated circuit configured with backside contacts that extend into the source or drain regions, in accordance with an embodiment of the present disclosure.

FIGS. 6A and 6B are cross-sectional views that illustrate another stage in the example process for forming an integrated circuit configured with backside contacts that extend into the source or drain regions, in accordance with an embodiment of the present disclosure.

FIGS. 7A and 7B are cross-sectional views that illustrate another stage in the example process for forming an integrated circuit configured with backside contacts that extend into the source or drain regions, in accordance with an embodiment of the present disclosure.

FIGS. 8A and 8B are cross-sectional views that illustrate another stage in the example process for forming an integrated circuit configured with backside contacts that extend into the source or drain regions, in accordance with an embodiment of the present disclosure.

FIGS. 9A and 9B are cross-sectional views that illustrate another stage in the example process for forming an integrated circuit configured with backside contacts that extend into the source or drain regions, in accordance with an embodiment of the present disclosure.

FIGS. 10A and 10B are cross-sectional views that illustrate another stage in the example process for forming an integrated circuit configured with backside contacts that extend into the source or drain regions, in accordance with an embodiment of the present disclosure.

FIGS. 11A and 11B are cross-sectional views that illustrate another stage in the example process for forming an integrated circuit configured with backside contacts that extend into the source or drain regions, in accordance with an embodiment of the present disclosure.

FIGS. 12A and 12B are cross-sectional views that illustrate another stage in the example process for forming an integrated circuit configured with backside contacts that extend into the source or drain regions, in accordance with an embodiment of the present disclosure.

FIGS. 13A and 13B are cross-sectional views that illustrate another stage in the example process for forming an integrated circuit configured with backside contacts that extend into the source or drain regions, in accordance with an embodiment of the present disclosure.

FIGS. 14A and 14B are cross-sectional views that illustrate another stage in the example process for forming an integrated circuit configured with backside contacts that extend into the source or drain regions, in accordance with an embodiment of the present disclosure.

FIGS. 15A and 15B are cross-sectional views that illustrate another stage in the example process for forming an integrated circuit configured with backside contacts that extend into the source or drain regions, in accordance with an embodiment of the present disclosure.

FIGS. 16A and 16B are cross-sectional views that illustrate another stage in the example process for forming an integrated circuit configured with backside contacts that extend into the source or drain regions, in accordance with an embodiment of the present disclosure.

FIGS. 17A and 17B are cross-sectional views that illustrate an example backside interconnect merged with a frontside interconnect within a source or drain region, in accordance with an embodiment of the present disclosure.

FIG. 18 illustrates a cross-sectional view of a chip package containing one or more semiconductor dies, in accordance with some embodiments of the present disclosure.

FIG. 19 is a flowchart of a fabrication process for a semiconductor device having backside contacts that extend into the source or drain regions, in accordance with an embodiment of the present disclosure.

FIG. 20 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having backside conductive contacts beneath source or drain regions that extend into the source or drain regions. The techniques can be used in any number of integrated circuit applications and are particularly useful with respect to logic and memory cells, such as those cells that use finFETs, gate-all-around transistors (e.g., ribbonFETs and nanowire FETs), or forksheet transistors. In an example, a semiconductor device includes a gate structure around or otherwise on a semiconductor region. The semiconductor region can be, for example, a fin of semiconductor material that extends from a source or drain region, or one or more nanowires, nanoribbon, or nanosheets of semiconductor material that extend from the source or drain region. The gate structure includes a gate dielectric (e.g., high-k gate dielectric material) and a gate electrode (e.g., conductive material such as workfunction material and/or gate fill metal). The substrate beneath the semiconductor device may be removed from the backside to expose a plug of sacrificial material previously formed beneath the source or drain region. The sacrificial plug is removed to form a backside cavity beneath the source or drain region. In an example, a dielectric liner is formed in the backside cavity followed by a directional etching process to form a deep recess through the bottom surface of the source or drain region. The backside cavity and corresponding deep recess are then filled with a conductive material to form the deep backside contact. In some such examples, a deep frontside contact is already present through a top surface of the source or drain region, such that the deep backside contact is formed on a portion of the deep frontside contact within the source or drain region. The resulting conductive structure creates a via passing through the entire thickness of the source or drain region. Numerous variations and embodiments will be apparent in light of this disclosure.

### General Overview

As previously noted above, there remain a number of non-trivial challenges with respect to integrated circuit fabrication. In more detail, backside interconnects have become increasingly more popular to route power and ground rails beneath the source or drain regions of various transistors. However, making effective connections between the backside interconnects and the source or drain regions is challenging. Fabrication restrictions often lead to greater-than-desired contact resistance between any backside contacts and the source or drain regions, which leads to decreased transistor performance.

Thus, and in accordance with an embodiment of the present disclosure, techniques are provided herein to form backside conductive contacts that extend into the source or drain regions to provide greater contact surface area. By contacting a greater portion of the source or drain region, the contact resistance can be drastically reduced. According to some embodiments, a sacrificial plug is formed beneath a given source or drain region and is exposed from the backside of the structure following the removal of the substrate. The sacrificial plug may then be selectively etched away to reveal a bottom surface of the source or drain region within a backside cavity. A dielectric liner may be conformally deposited within the cavity to cover the sidewalls and the exposed surface of the source or drain region. A directional etch process (e.g., reactive ion etching) may be used to punch through a portion of the dielectric liner on the source or drain region and continue etching a recess through the bottom surface of the source or drain region. One or more conductive materials may then be formed within the backside cavity and recess to form the backside contact that extends into the source or drain region. According to some embodiments, a similar process may be performed on the frontside of the source or drain region (e.g., prior to the removal of the substrate form the backside), to form a frontside contact that extends below the top surface of the source or drain region. In such examples, the backside contact may meet the previously-formed frontside contact within the source or drain region to form a merged or combined contact that extends through the entire height of the source or drain region. The merged or combined contact not only makes electrical contact with the given source or drain region, but can also act as a conductive pathway to feed power or signals between topside interconnects and backside interconnects of the die.

According to an embodiment, an integrated circuit includes a semiconductor device having a semiconductor region extending in a first direction from a source or drain region and a gate structure extending in a second direction over the semiconductor region, a dielectric layer beneath the gate structure, a backside conductive contact extending through the dielectric layer and through at least a portion of a total height of the source or drain region, and a dielectric liner on sidewall surfaces of the backside conductive contact. The dielectric liner is between the backside conductive contact and the dielectric layer, and at least a portion of the dielectric liner contacts a bottom surface of the source or drain region.

According to another embodiment, a method of forming an integrated circuit includes: forming a fin comprising semiconductor material, the fin extending above a substrate; forming a dielectric layer adjacent to a subfin of the fin; forming a sacrificial gate and spacer structures over the fin; removing portions of the fin not covered by the sacrificial gates and spacer structures; removing a subfin region of the fin to form a subfin cavity; forming a sacrificial plug within the subfin cavity; forming a source or drain region at exposed ends of the semiconductor material and over the sacrificial plug; removing a portion of the substrate from a backside of the integrated circuit to expose a bottom surface of the subfin and a bottom surface of the sacrificial material; removing the sacrificial plug from the backside to form a backside cavity; forming a dielectric liner within the backside cavity; removing a portion of the dielectric liner on a bottom surface of the source or drain region; etching a recess into the exposed bottom surface of the source or drain region; and forming a conductive contact within both the backside cavity and within the recess.

According to another embodiment, an integrated circuit includes a semiconductor device having a semiconductor region extending in a first direction from a source or drain region and a gate structure extending in a second direction over the semiconductor region, a dielectric layer beneath the gate structure, and a conductive contact extending through the dielectric layer and through an entire height of the source or drain region. The conductive contact has a first section having a tapering width from a bottom surface of the source or drain region to a top of the first section, and a second section having a tapering width from a top surface of the source or drain region to the bottom of the second section. The conductive contact has a smallest width at an interface between the first section and the second section of the conductive contact.

The techniques can be used with any type of non-planar transistors, including finFETs (sometimes called double-gate transistors, or tri-gate transistors), or nanowire and nanoribbon transistors (sometimes called gate-all-around transistors), or stacked versions of any of these architectures, to name a few examples. The source and drain regions can be, for example, doped portions of a given fin or substrate or epitaxial regions that are deposited during an etch-and-replace source/drain forming process. The dopant type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of backside contacts beneath source or drain regions. One or more of the backside contacts would extend upwards into the corresponding source or drain regions. In some examples, one or more of the backside contacts would be observed as being merged with or otherwise contacting one or more corresponding frontside contacts in the source or drain regions.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer. Multiple formed layers of the same material (e.g., a same dielectric material) on one another may be collectively considered a single layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

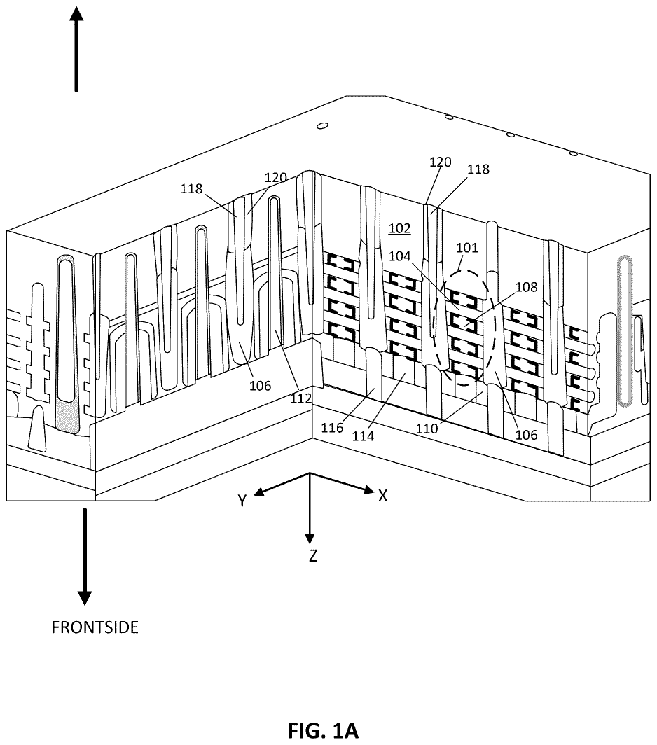

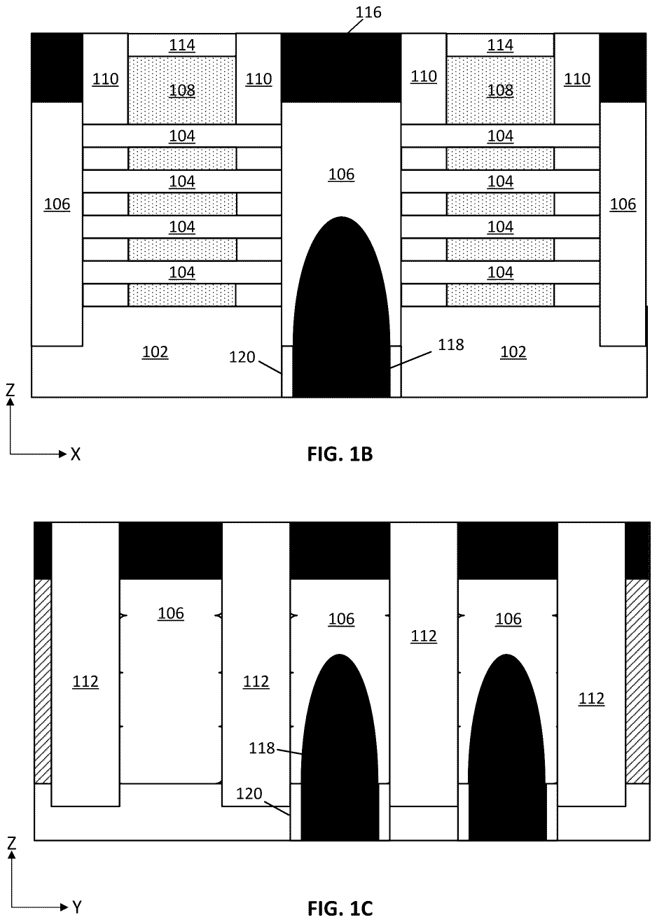

FIG. 1A is an isometric view of a portion of an integrated circuit that includes various semiconductor devices 101, in accordance with an embodiment of the present disclosure. Each of the semiconductor devices may be non-planar metal oxide semiconductor (MOS) transistors, such as tri-gate (e.g., finFET), gate-all-around (GAA), or forksheet transistors, although other transistor topologies and types could also benefit from the techniques provided herein. The examples herein illustrate semiconductor devices with a GAA structure (e.g., having nanoribbons or nanowires that extend between source and drain regions). Note that the structure in FIG. 1A is flipped upside down such that the backside of the structure is on top and the frontside of the structure is on the bottom.

The semiconductor material used in each of the semiconductor devices may be formed from a semiconductor substrate. In some embodiments, the substrate is removed from the backside and replaced with any number of dielectric layers to form backside interconnects beneath various transistor elements. In the example illustrated in FIG. 1A, a base dielectric layer 102 may be formed beneath semiconductor devices 101. In some examples, subfin regions of semiconductor devices 101 are removed from the backside and replaced with dielectric material to form at least part of the base dielectric layer 102. One or more additional dielectric layers may be formed beneath base dielectric layer 102 to form backside interconnects.

The one or more semiconductor regions of the devices may include fins that can be, for example, native to the substrate (formed from the substrate itself), such as silicon fins etched from a bulk silicon substrate. Alternatively, the fins can be formed of material deposited onto the substrate. In one such example case, a blanket layer of silicon germanium (SiGe) can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons during a gate forming process where one type of the alternating layers is selectively etched away so as to liberate the other type of alternating layers within the channel region, so that a gate-all-around process can then be carried out. Again, the alternating layers can be blanket deposited and then etched into fins or deposited into fin-shaped trenches.

Each semiconductor device 101 includes one or more semiconductor regions, such as one or more nanoribbons 104 extending between epitaxial source or drain regions 106 in a first direction along the X-axis. According to some embodiments, source or drain regions 106 may be either n-type or p-type regions. In some examples, n-type source or drain regions include silicon doped with phosphorous or arsenic, and p-type source or drain regions include silicon germanium doped with boron. Other examples may be configured differently.

A gate structure 108 that includes a gate electrode and a gate dielectric extends over the one or more semiconductor regions of a given semiconductor device 101 in a second direction along the Y-axis to form the transistor gate. The gate electrode may represent any number of conductive layers and the gate dielectric may represent any number of dielectric layers. The gate electrode may include any sufficiently conductive material such as a metal, metal alloy, or doped polysilicon. In some embodiments, the gate electrode includes one or more workfunction metals around the one or more semiconductor regions. The gate electrode may also include a fill metal or other conductive material around the workfunction metals to provide the whole gate electrode structure. The gate dielectric may include any gate dielectric material(s). In some embodiments, the gate dielectric includes a layer of native oxide material (e.g., silicon oxide) on the nanoribbons 104 or other semiconductor regions, and a layer of high-k dielectric material (e.g., hafnium oxide) on the native oxide. According to some embodiments, spacer structures 110 are present along the sidewalls of gate structures 108. Spacer structures 110 may be any dielectric material, such as silicon nitride or silicon oxynitride, and provide separation between a given gate structure 108 and the adjacent source or drain region 106. Spacer structures 110 may run along sidewalls of gate structure 108 in the second direction and extend the entire height of gate structure 108 along the Z-axis. In this example, spacer structures 110 generally include both the upper spacers (sometimes called gate spacers, which may be formed during dummy or initial gate formation) and lower spacers (sometimes called inner gate spacers, which may be formed during source/drain processing).

According to some embodiments, adjacent gate structures 108 may be separated from one another along the second direction (e.g., along the Y-axis) by a dielectric wall 112 (sometimes referred to as a gate cut). Any number of suitable dielectric materials can be used for dielectric wall 112, such as silicon nitride or silicon oxynitride or low-k versions of these (e.g., porous silicon oxynitride). Any number of dielectric walls 112 may run lengthwise along the X-axis and parallel to one another, and may extend along the Z-axis at least through an entire thickness of one or more gate structures 108 and up to (or through) a cap layer 114 on a top surface of gate structures 108, as shown in this example. According to some embodiments, dielectric wall 112 continues to extend along the X-axis between multiple pairs of semiconductor devices and between the source or drain regions 106 of the devices.

Dielectric cap layer 114 may run lengthwise along the Y-axis along the top surface of gate structures 108. Cap layer 114 may include the same dielectric material as dielectric wall 112, in some examples.

As further shown in the example of FIG. 1A, any number of frontside conductive contacts 116 are on the top surfaces of corresponding source or drain regions 106. Adjacent frontside conductive contacts 116 may be separated by dielectric wall 112 along the second direction or may connect together over or through dielectric wall 112 (e.g., via a bridging conductor). Frontside conductive contacts 116 can include any suitable conductive material, such as tungsten, ruthenium, cobalt, molybdenum, titanium, tantalum, or other metals or alloys thereof. Frontside conductive contacts 116 may be formed together such that they include the same conductive material.

As further shown in the example of FIG. 1A, one or more backside conductive contacts 118 extend through a thickness of base dielectric layer 102 and through at least a portion of the total thickness of source or drain regions 106, according to some embodiments. Backside conductive contacts 118 may include any of the same materials noted above for frontside conductive contacts 116. In some examples, backside conductive contacts 118 and frontside conductive contacts 116 include the same conductive material. Backside conductive contacts 118 may connect to backside power or ground rails, or to a signal routing interconnect structure. According to some embodiments, additional dielectric layers and conductive elements can be formed beneath base dielectric layer 102 to create a backside interconnect structure (such as a power delivery network and/or signal routing network).

According to some embodiments, a dielectric liner 120 is present around portions of backside contacts 118. Dielectric liner 120 may be formed within backside cavities prior to the formation of backside contacts 118, such that backside contacts 118 punch through a portion of dielectric liner 120 before extending into source or drain regions 106. Dielectric liner 120 may be any suitable dielectric material, such as silicon nitride, silicon oxycarbonitride, or titanium oxide. Dielectric liner 120 may have a thickness of less than 5 nm, or between 1 nm and 3 nm.

FIG. 1B illustrates a cross-section view across the XZ plane from FIG. 1A and FIG. 1C illustrates a cross-section view across the YZ plane from FIG. 1A, according to some embodiments. Backside contacts 118 may extend through at least 30%, at least 40%, at least 50%, or at least 60% of an entire height (e.g., along the Z direction) of source or drain regions 106. In some examples, backside contacts 118 extend through a portion of source or drain regions 106 that is above an XY plane along a bottommost surface of the lowest set of nanoribbons 104 (e.g., the lowest surface of the semiconductor region extending between the source or drain regions). In some examples, backside contacts 118 extend through a portion of source or drain regions 106 that is above an XY plane along the bottom surface of the second nanoribbons 104 from the bottom. Note that dielectric liner 120 is on the sidewalls of a bottom portion of backside contacts 118 beneath source or drain regions 106, and that a portion of dielectric liner 120 is directly on a bottom surface of source or drain regions 106. The illustrations of backside contacts 118 shown in FIGS. 1B and 1C are not drawn to scale and are provided to give a general understanding of the example geometry of backside contacts 118.

### Fabrication Methodology

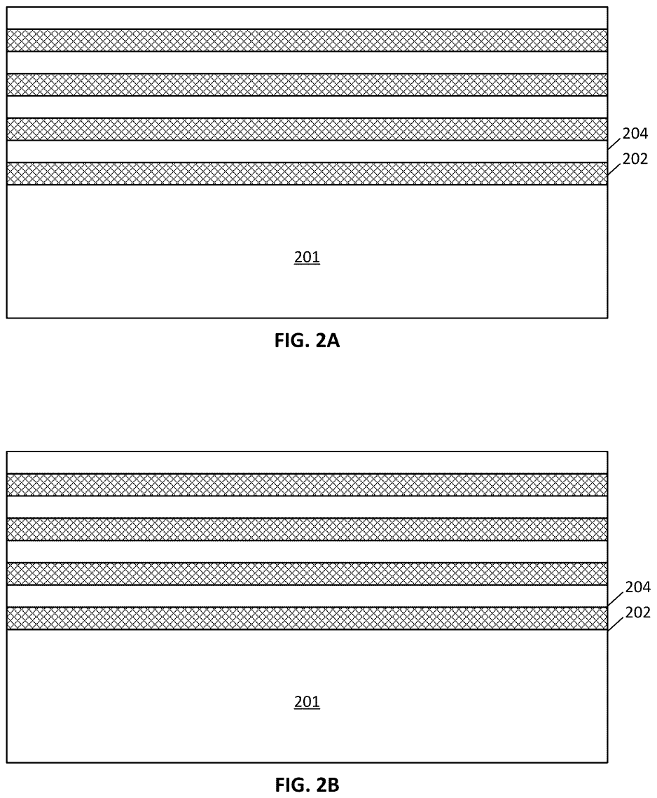

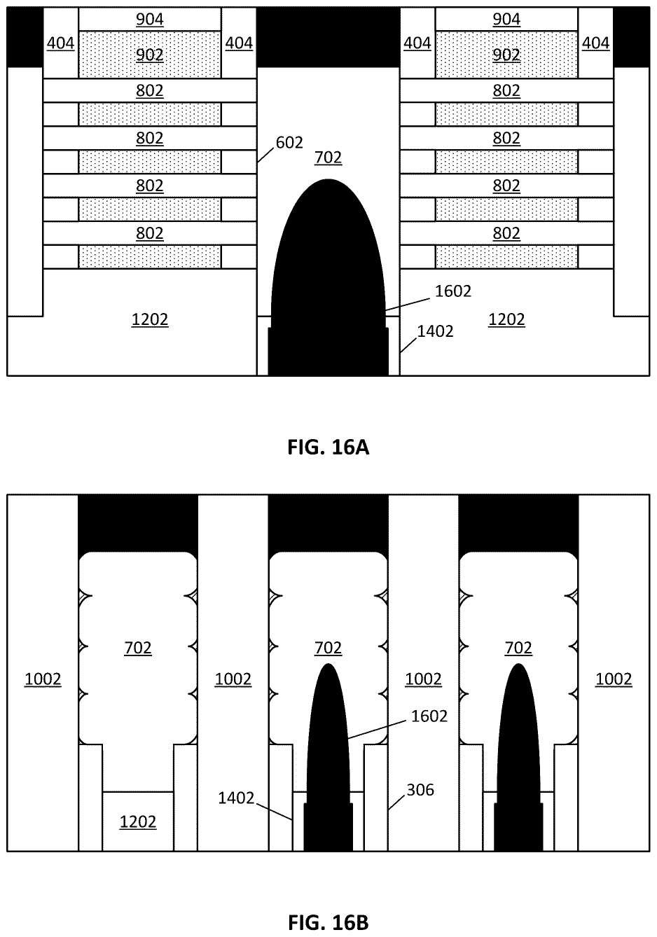

FIGS. 2A-16A and 2B-16B include cross-sectional views that collectively illustrate an example process for forming an integrated circuit configured with backside contacts that extend into the source or drain regions, in accordance with an embodiment of the present disclosure. FIGS. 2A-16A represent a similar cross-sectional view taken across the XZ plane in FIG. 1A, while FIGS. 2B-16B represent a cross-sectional view taken across the YZ in FIG. 1A. Each set of figures sharing the same letter shows an example structure that results from the process flow up to that point in time, so the depicted structure evolves as the process flow continues, culminating in the structure shown in FIGS. 16A and 16B, which is similar to the structure shown in FIGS. 1B and 1C. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIGS. 2A and 2B each illustrates a cross-sectional view taken through a substrate 201 having a series of material layers formed over the substrate, according to an embodiment of the present disclosure. Alternating material layers may be deposited over a substrate 201 including sacrificial layers 202 alternating with semiconductor layers 204. The alternating layers are used to form GAA transistor structures. Any number of alternating sacrificial layers 202 and semiconductor layers 204 may be deposited over substrate 201.

Substrate 201 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, semiconductor layers 204 have a different material composition than sacrificial layers 202. In some embodiments, semiconductor layers 204 are silicon germanium (SiGe) while sacrificial layers 202 include a semiconductor material suitable for use as a nanoribbon such as silicon (Si), SiGe, germanium, or III-V materials like indium phosphide (InP) or gallium arsenide (GaAs). In examples where SiGe is used in each of semiconductor layers 204 and in sacrificial layers 202, the germanium concentration is different between semiconductor layers 204 and sacrificial layers 202. For example, semiconductor layers 204 may include a higher germanium content compared to sacrificial layers 202. In some examples, sacrificial layers 202 may be doped with either n-type dopants (to produce a p-channel transistor) or p-type dopants (to produce an n-channel transistor).

While dimensions can vary from one example embodiment to the next, the thickness of each semiconductor layer 204 may be between about 5 nm and about 20 nm. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any known material deposition technique, such as chemical vapor deposition (CVD), plasma-enhanced chemical vapor deposition (PECVD), physical vapor deposition (PVD), or atomic layer deposition (ALD), or epitaxial growth.

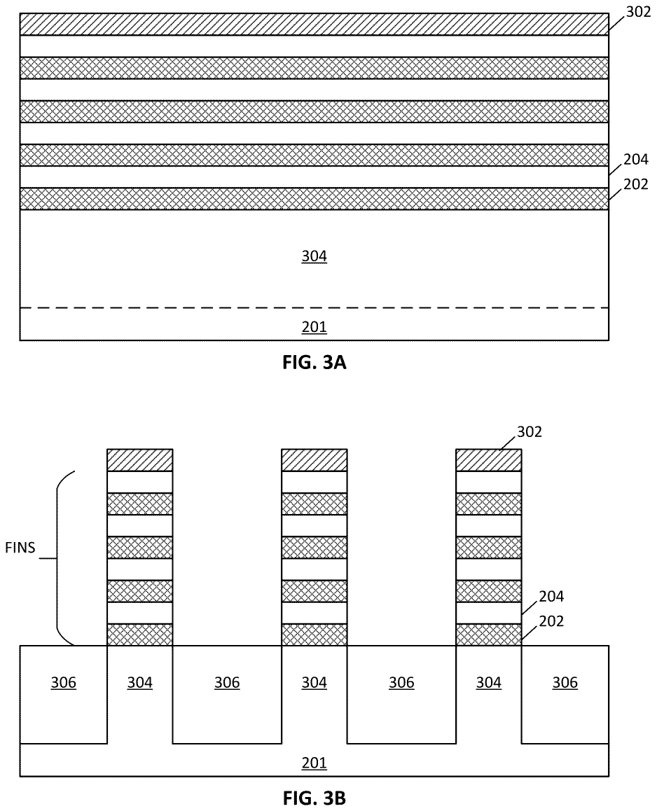

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. Cap layer 302 extends along the top of each fin in a first direction, as seen in FIG. 3A.

According to some embodiments, an anisotropic etching process through the layer stack continues into at least a portion of substrate 201. Portions of substrate 201 beneath the fins are not etched and yield subfin regions 304. The etched portion of substrate 201 may be filled with a dielectric fill 306 that acts as shallow trench isolation (STI) between adjacent fins. Dielectric fill 306 may be any dielectric material such as silicon dioxide. Subfin regions 304 represent remaining portions of substrate 201 between dielectric fill 306, according to some embodiments.

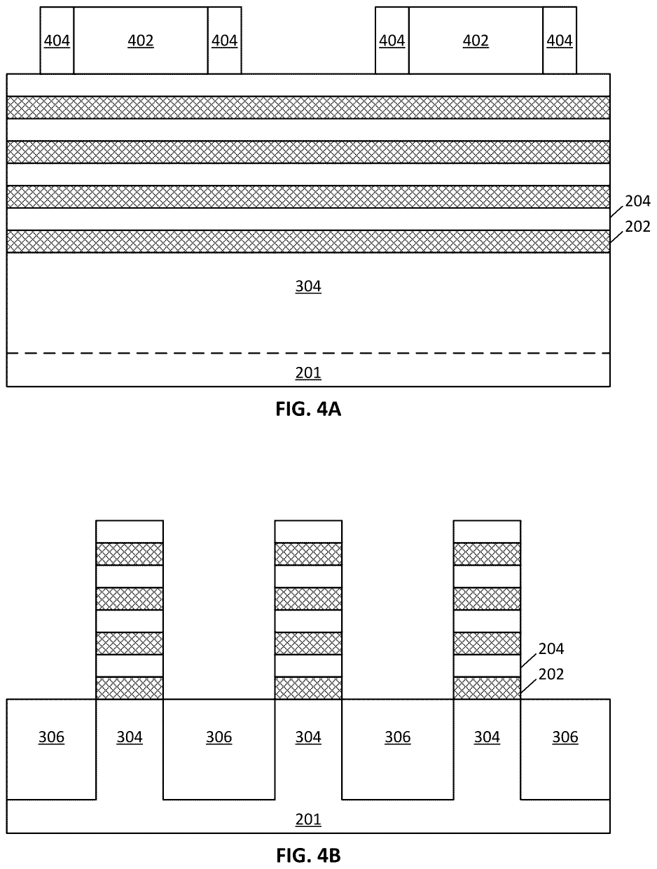

FIGS. 4A and 4B depict cross-section views of the structures shown in FIGS. 3A and 3B following the formation of sacrificial gates 402, according to some embodiments. A gate masking layer may first be patterned in strips that extend orthogonally across each of the fins (e.g., in a second direction) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gate 402 may be any material that can be selectively removed without damaging the semiconductor material of the fins. In some examples, sacrificial gate 402 includes polysilicon.

According to some embodiments, spacer structures 404 (also referred to as gate spacers or upper gate spacers) are formed along the sidewalls of sacrificial gates 402. Spacer structures 404 may be deposited and then etched back such that spacer structures 404 remain mostly only on sidewalls of any exposed structures. In the cross-section view of FIG. 4B, spacer structures 404 may also be formed along sidewalls of the exposed fins over dielectric fill 306. Such sidewall spacers on the fins can be removed during later processing when forming the source or drain regions, or portions of the spacers may remain in the final structure. According to some embodiments, spacer structures 404 may be any suitable dielectric material, such as silicon nitride, silicon carbon nitride, or silicon oxycarbonitride. In one such embodiment, spacer structures 404 comprise a nitride and dielectric fill 306 comprises an oxide, so as to provide a degree of etch selectivity during final gate processing. Other etch selective dielectric schemes (e.g., oxide/carbide, carbide/nitride) can be used as well for spacer structures 404 and dielectric fill 306. In other embodiments, spacer structures 404 and dielectric fill 306 are compositionally the same or otherwise similar, where etch selectivity is not employed.

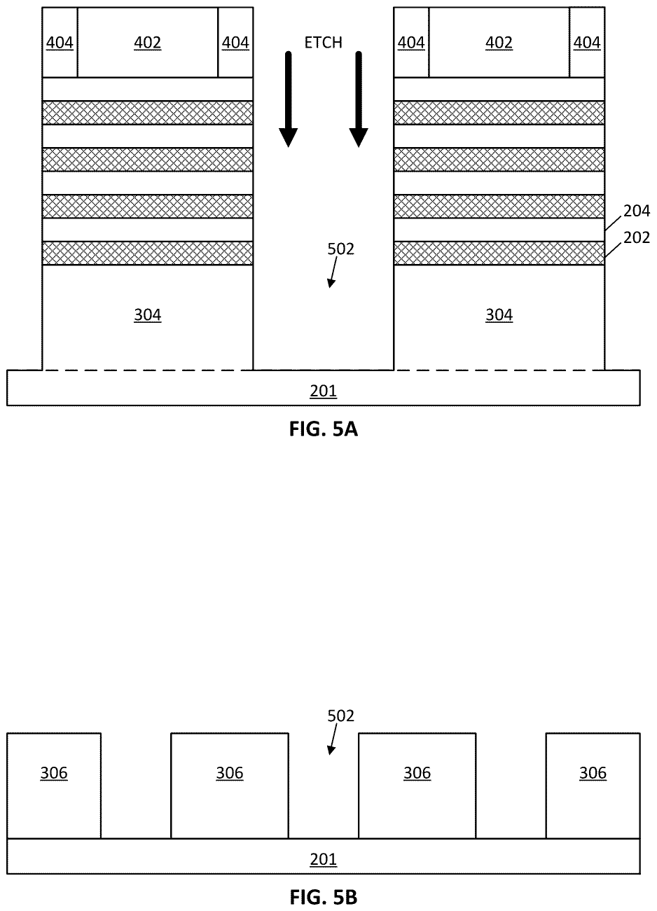

FIGS. 5A and 5B depict cross-section views of the structures shown in FIGS. 4A and 4B following the removal of exposed portions of the fins not protected by sacrificial gates 402 and spacer structures 404, according to some embodiments. The exposed fin portions may be removed using any anisotropic etching process, such as RIE. The removal of the exposed fin portions creates source or drain trenches that alternate with gate trenches (currently filled with sacrificial gates 402) along the first direction, according to some embodiments. In some embodiments, at least a portion of subfin regions 304 are also removed such that a top surface of subfin regions 304 is recessed below a top surface of dielectric fill 306. In some embodiments, subfin regions 304 within the source/drain trenches are removed entirely (as illustrated), to yield subfin cavities 502.

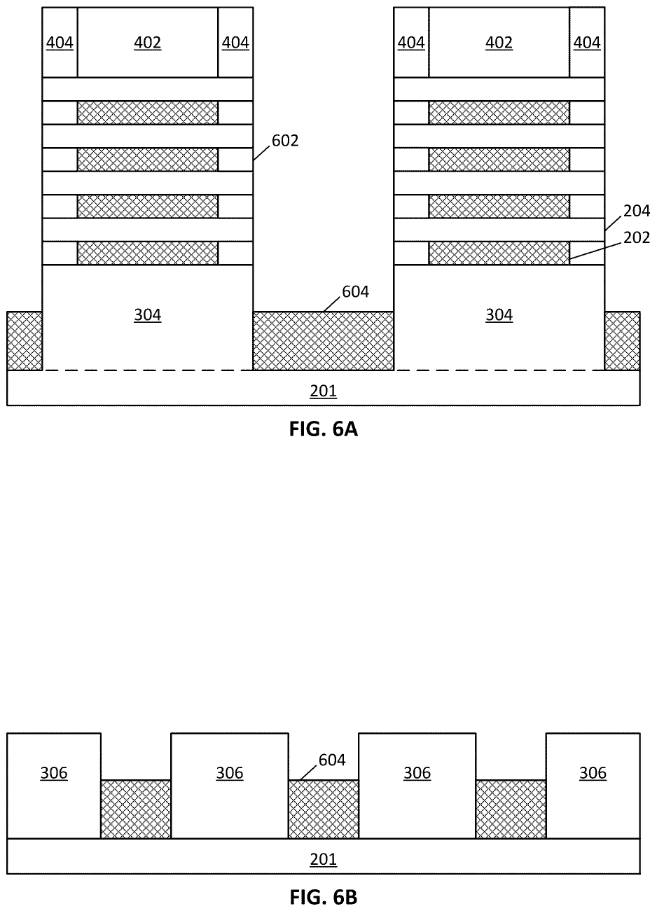

FIGS. 6A and 6B depict cross-section views of the structures shown in FIGS. 5A and 5B following the removal of portions of sacrificial layers 202 and subsequent formation of internal spacers 602 (sometimes called lower gate spacers), according to an embodiment of the present disclosure. An isotropic etching process may be used to selectively recess the exposed ends of each sacrificial layer 202 (e.g., while etching comparatively little of semiconductor layers 204). Internal spacers 602 may have a material composition that is similar to or the exact same as spacer structures 404. Accordingly, internal spacers 602 may be any dielectric material that exhibits high etch selectively to semiconductor materials such as silicon and/or silicon germanium. Internal spacers 602 may be, for example, conformally deposited over the sides of the fin structure using a conformal deposition process like CVD or ALD and then etched back using an isotropic etching process to expose the ends of semiconductor layers 204. According to some embodiments, internal spacers 602 have a similar width (e.g., along the first direction) to spacer structures 404. According to some embodiments, dielectric material used to form internal spacers 602 may remain at the bottom of subfin cavities 502 as sacrificial plugs 604. In some embodiments, a separate material deposition process is performed to fill the source/drain trenches with a sacrificial material that is subsequently recessed to form sacrificial plugs 604. The top surface of sacrificial plugs 604 may be below a top surface of the adjacent dielectric fill 306 and/or the adjacent subfin regions 304. As noted above, sacrificial plugs 604 may be the same dielectric material as internal spacers 602. In some examples, sacrificial plugs 604 include aluminum oxide or titanium nitride.

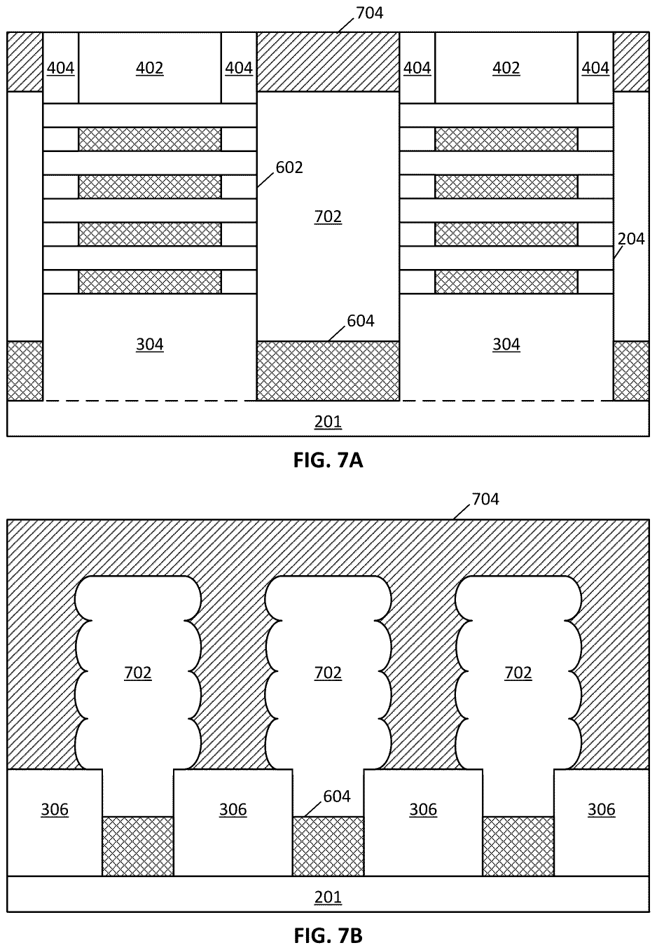

FIGS. 7A and 7B depict cross-section views of the structure shown in FIGS. 6A and 6B, respectively, following the formation of source or drain regions 702 within the source/drain trenches, according to some embodiments. Source or drain regions 702 may be formed in the areas that had been previously occupied by the exposed fins between spacer structures 404. According to some embodiments, source or drain regions 702 are epitaxially grown from the exposed semiconductor material at the ends of semiconductor layers 204. Any of source or drain regions 702 may be NMOS source or drain regions (e.g., epitaxial silicon) or PMOS source or drain regions (e.g., epitaxial SiGe). Source or drain regions of one dopant type may be formed first before the formation of source or drain regions of the other dopant type. In some examples, adjacent source or drain regions 702 along the second direction (e.g., as illustrated in FIG. 7B) have alternating dopant types. Source or drain regions 702 may be formed directly over sacrificial plugs 604. In some examples, lower portions of source or drain regions 702 are epitaxially grown from the exposed sidewall surfaces of subfin regions 304 above sacrificial plugs 604.

According to some embodiments, a dielectric fill 704 is provided between adjacent source or drain regions 702. In some examples, dielectric fill 704 occupies a remaining volume within the source/drain trench around and over source or drain regions 702. Dielectric fill 704 may be any dielectric material, such as silicon dioxide. In some examples, dielectric fill 704 extends up to and planar with a top surface of spacer structures 404 (e.g., following a polishing procedure). A planarization process such as chemical mechanical polish (CMP) can be used to remove any excess dielectric fill 704 and planarize the structure, as shown.

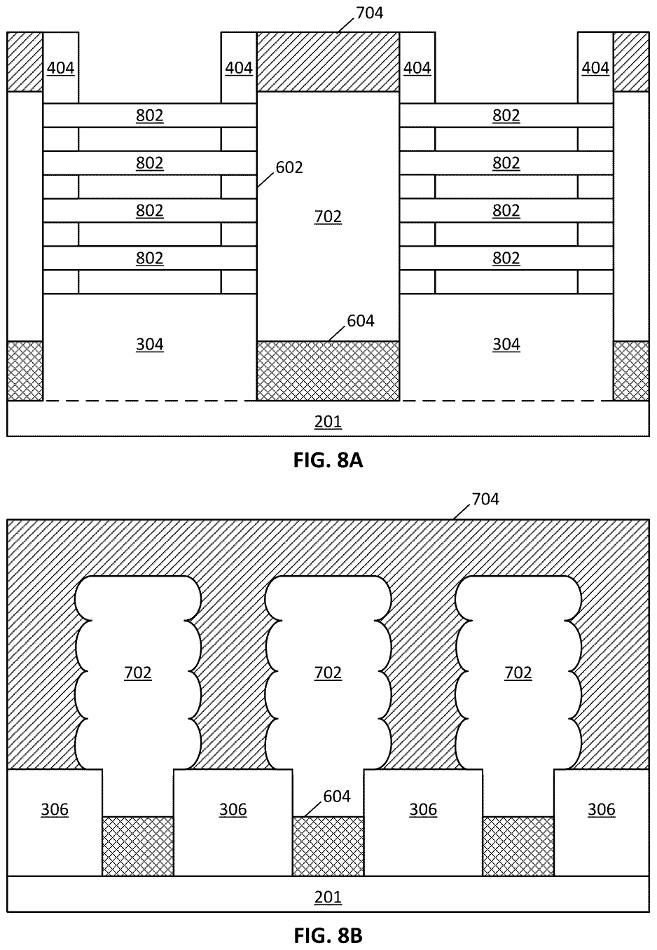

FIGS. 8A and 8B depict cross-section views of the structure shown in FIGS. 7A and 7B, respectively, following the removal of sacrificial gates 402 and sacrificial layers 202, according to some embodiments. In examples where gate masking layers are still present, they would be removed at this time. Once sacrificial gates 402 are removed, the fins extending between spacer structures 404 are exposed.

In the example where the fins include alternating semiconductor layers, sacrificial layers 202 are selectively removed to leave behind nanoribbons 802 that extend between corresponding source or drain regions 702. Each vertical set of nanoribbons 802 represents the semiconductor region (or channel region) of a different semiconductor device. Note that nanoribbons 802 may have any geometry and the use of the term nanoribbon is not intended to exclude any particular geometries usable for a gate-all-around channel region (such as nanowires). In other embodiments, nanoribbons 802 of a given channel region may be a single fin structure, so as to provide a double-gate or tri-gate configuration. In still other embodiments, nanoribbons 802 of a given channel region may be nanosheets extending laterally (out of page) from a dielectric wall, so as to provide a forksheet configuration. Sacrificial gates 402 and sacrificial layers 202 may be removed using the same isotropic etching process or different isotropic etching processes.

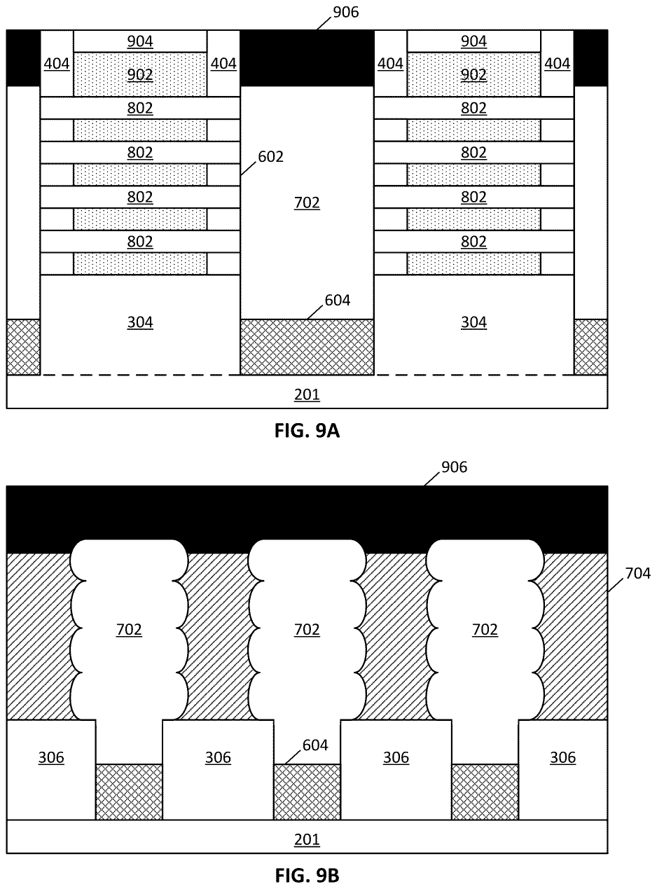

FIGS. 9A and 9B depict cross-section views of the structure shown in FIGS. 8A and 8B, respectively, following the formation of gate structures 902, subsequent gate caps 904, and frontside contacts 906, according to some embodiments. Gate structures 902 may each include a gate electrode on a gate dielectric. The gate dielectric may be first formed around nanoribbons 802 prior to the formation of the gate electrode, which may include one or more conductive layers. The gate dielectric may include any gate dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric includes a layer of hafnium oxide with a thickness between about 1 nm and about 5 nm. In some embodiments, the gate dielectric may include one or more silicates (e.g., titanium silicate, tungsten silicate, niobium silicate, and silicates of other transition metals). In some cases, the gate dielectric includes a first layer on nanoribbons 802, and a second layer on the first layer. The first layer can be, for instance, an oxide of the semiconductor material of nanoribbons 802 (e.g., silicon dioxide) and the second layer can be a high-k dielectric material (e.g., hafnium oxide).

The one or more conductive layers that make up the gate electrode may be deposited using electroplating, electroless plating, CVD, PECVD, ALD, or PVD, to name a few examples. In some embodiments, the gate electrode includes doped polysilicon, a metal, or a metal alloy. Example metals or metal alloys include aluminum, tungsten, cobalt, molybdenum, ruthenium, titanium, tantalum, copper, and carbides and nitrides thereof. The gate electrode may include, for instance, a metal fill material along with one or more workfunction layers, resistance-reducing layers, and/or barrier layers. The workfunction layers can include, for example, p-type workfunction materials (e.g., tungsten) for PMOS gates, or n-type workfunction materials (e.g., titanium aluminum carbide) for NMOS gates.

Gate cap 904 may be formed by first recessing the gate electrode and filling the recess with a dielectric material. The dielectric material may then be polished such that its top surface is substantially coplanar with a top surface of spacer structures 404.

According to some embodiments, frontside contacts 906 may include any conductive material, such as tungsten, molybdenum, cobalt, titanium, tantalum, or ruthenium, or any alloys thereof, for making electrical contact with the underlying source or drain regions 702. As seen in the cross section of FIG. 9B, a portion of dielectric fill 704 is recessed to expose at least the top surfaces of any number of source or drain regions 702 and a frontside contact 906 is formed within the recess using any suitable metal deposition process. According to some embodiments, frontside contacts 906 include one or more silicide (or germanide, as the case may be) layers directly on the exposed surfaces of source or drain regions 702. Frontside contacts 906 may extend along the source/drain trenches in the second direction on any number of source or drain regions 702.

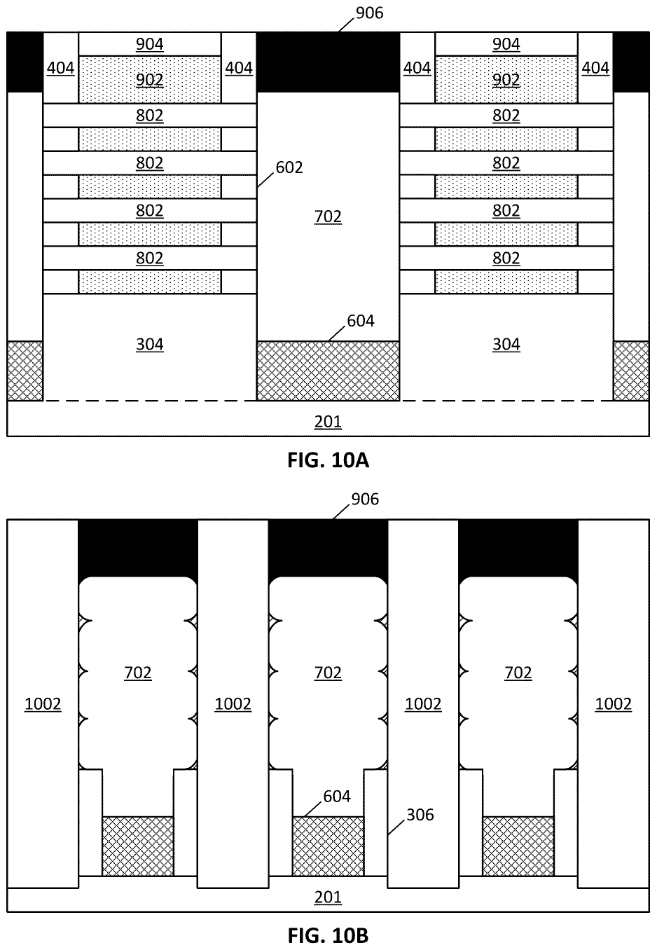

FIGS. 10A and 10B depict cross-section views of the structure shown in FIGS. 9A and 9B, respectively, following the formation of dielectric walls 1002 extending in the first direction between devices, according to some embodiments. Dielectric walls 1002 extend to a depth at least through an entire thickness of gate structures 902 to isolate the gate structures along the second direction. In some embodiments, dielectric walls 1002 extend into at least a portion of dielectric fill 306 or through an entire thickness of dielectric fill 306. In some embodiments, dielectric walls 1002 extend entirely through dielectric fill 306 and into a portion of substrate 201.

According to some embodiments, dielectric walls 1002 may be formed by first forming corresponding gate cut recesses through gate cap 904, contact 906 and gate structures 902 using any metal gate etch process that iteratively etches through portions of the gate electrode while simultaneously protecting the sidewalls of the recess from lateral etching to provide a high height-to-width aspect ratio recess (e.g., aspect ratio of 5:1 or higher, or 10:1 or higher). As shown in FIG. 10B, the gate cut recesses extend in the first direction (e.g., into and out of the page) through multiple gate trenches and source/drain trenches to isolate adjacent gate structures and source or drain regions. The gate cut recesses may be filled with one or more dielectric materials to form dielectric walls 1002. For example, dielectric walls 1002 may include only silicon dioxide or silicon nitride or silicon carbide. In some examples, dielectric walls 1002 include a first dielectric layer deposited first and a second dielectric layer or dielectric fill formed on the first dielectric layer. The first dielectric layer may include a high-k dielectric material (e.g., materials with a dielectric constant higher than that of silicon oxide or higher than 3.9) while the second dielectric layer may include a low-k dielectric material (e.g., materials with a dielectric constant equal to or lower than that of silicon oxide, such as porous silicon oxide, or equal to or lower than 3.9). In the illustrated example, dielectric walls 1002 separate each of source or drain regions 702 along the second direction along with their associated frontside contacts 906. In some examples where devices are closely packed, dielectric walls 1002 may contact one or more sidewalls of source or drain regions 702. In some examples, dielectric walls 1002 exist between some adjacent pairs of source or drain regions 702, but not between every adjacent pair of source or drain regions 702.

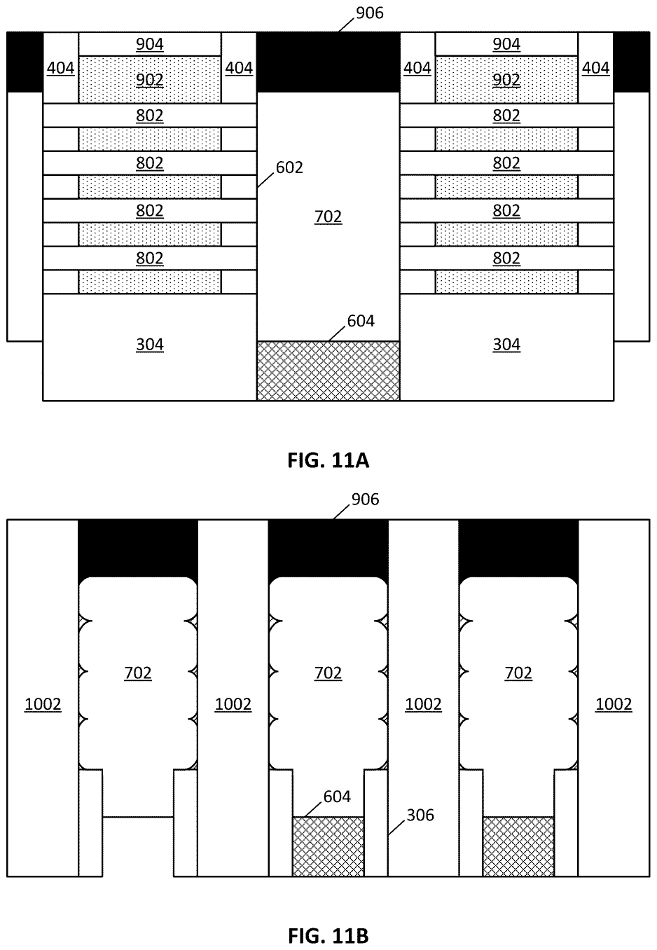

FIGS. 11A and 11B depict cross-section views of the structure shown in FIGS. 10A and 10B, respectively, following the removal of substrate 201 from the backside, which exposes a bottom surface of subfin regions 304, a bottom surface of dielectric fill 306, and a bottom surface of sacrificial plugs 604, according to some embodiments. According to some embodiments, any suitable backside lithography processes may be performed to remove one or more of sacrificial plugs 604. In the illustrated example, the leftmost sacrificial plug in FIG. 11B has been removed. These plugs may be removed beneath source or drain regions that will not have a backside contact, as will be described herein. Any suitable isotropic etching process may be used to remove the material of sacrificial plugs 604 while etching little to none of the surrounding subfin regions 304 and dielectric fill 306.

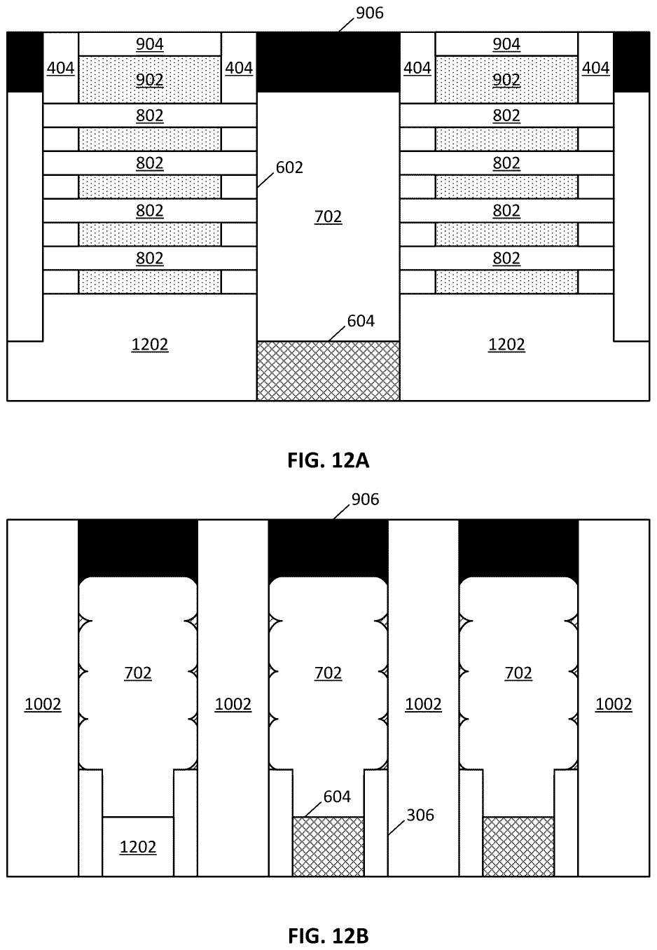

FIGS. 12A and 12B depict cross-section views of the structure shown in FIGS. 11A and 11B, respectively, following the removal of subfin regions 304 and subsequent formation of a base dielectric structure 1202, according to some embodiments. Base dielectric structure 1202 may represent any number of deposited dielectric material layers and may include any suitable dielectric material, such as silicon dioxide. According to some embodiments, a backside of base dielectric structure 1202 is polished back until a bottom surface of sacrificial plugs 604 are exposed once again.

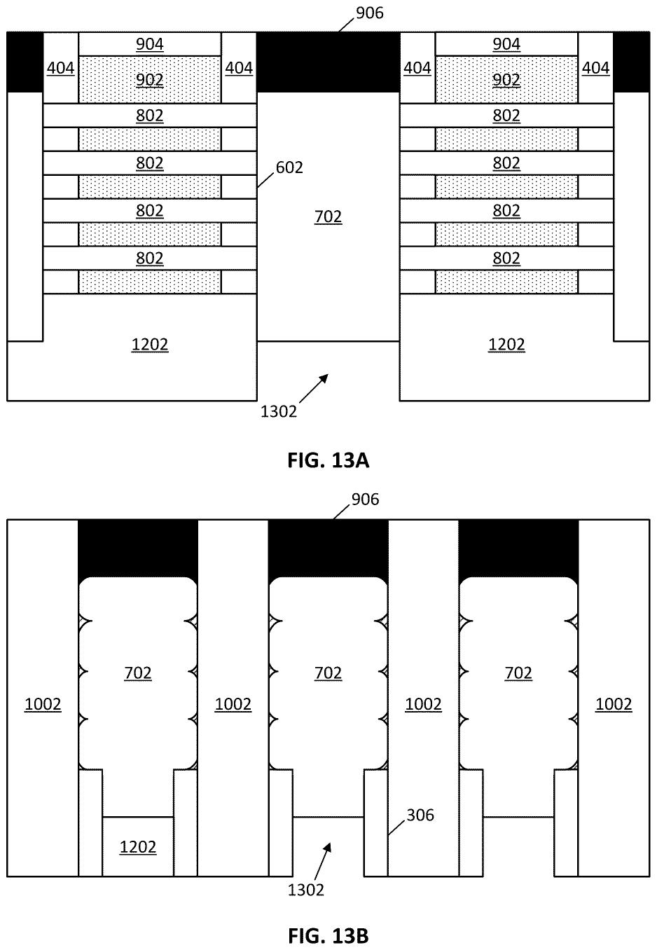

FIGS. 13A and 13B depict cross-section views of the structure shown in FIGS. 12A and 12B, respectively, following the removal of the remaining sacrificial plugs 604 to form corresponding backside cavities 1302 beneath source or drain regions 702, according to some embodiments. Any suitable isotropic etching process may be used to remove the material of the remaining sacrificial plugs 604 while etching little to none of the surrounding base dielectric structure 1202 and dielectric fill 306. At least a bottom surface of source or drain regions 702 may be exposed within backside cavities 1302.

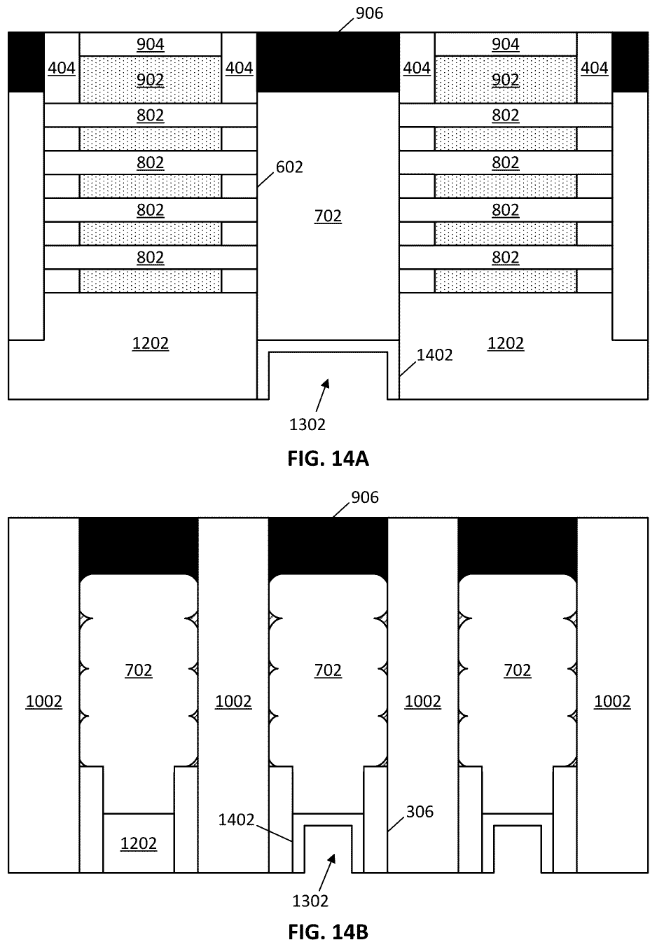

FIGS. 14A and 14B depict cross-section views of the structure shown in FIGS. 13A and 13B, respectively, following the formation of a dielectric liner 1402, according to some embodiments. Dielectric liner 1402 may be any suitable dielectric material, such as silicon nitride or titanium oxide, and may have a thickness between about 1 nm and about 3 nm. Dielectric liner 1402 may be deposited using any suitable conformal deposition technique, such as chemical vapor deposition (CVD), plasma-enhanced chemical vapor deposition (PECVD), or atomic layer deposition (ALD). Dielectric liner 1402 may be formed such that is covers the sidewalls of backside cavities 1302 and the exposed bottom surfaces of source or drain regions 702. In some examples, portions of dielectric liner 1402 continue to extend along the bottom surface of base dielectric structure 1202.

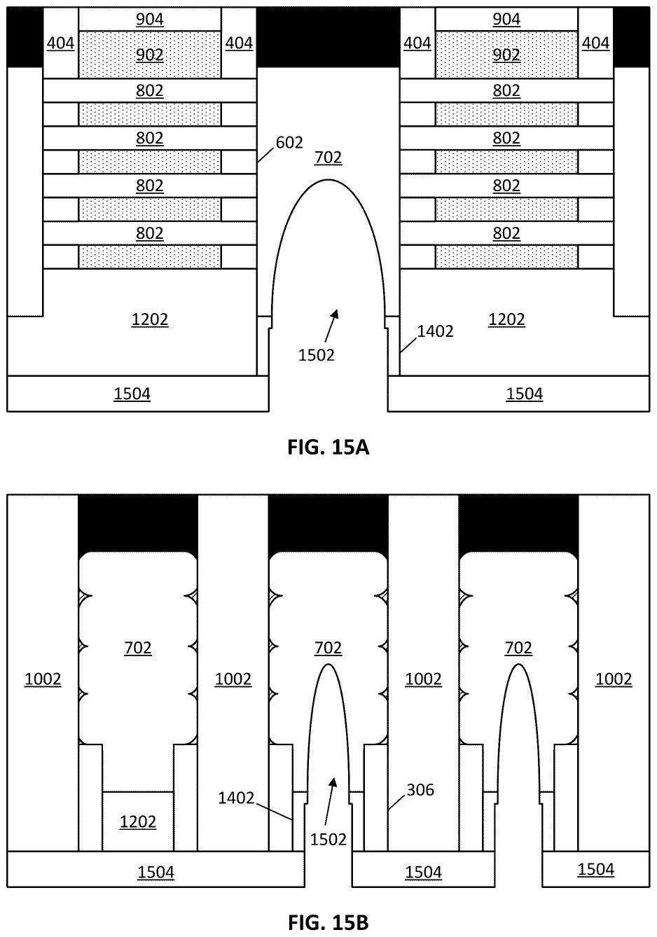

FIGS. 15A and 15B depict cross-section views of the structure shown in FIGS. 14A and 14B, respectively, following another etching process to form recesses 1502 extending into source or drain regions 702, according to some embodiments. A masking layer 1504 may first be formed over the bottom surface of base dielectric structure 1202, while little to none of masking layer 1504 is formed within backside cavities 1302. In some embodiments, masking layer 1504 is deposited using physical vapor deposition (PVD), such as sputtering, to preferentially deposit the material on the planar bottom surface of base dielectric structure 1202. Masking layer 1504 may include any suitable dielectric hard mask material or a carbon hard mask (CHM).

Following the formation of masking layer 1504, a directional RIE process may be performed to punch through a portion of dielectric liner 1402 on the bottom surface of source or drain regions 702. The etching process may then continue into source or drain regions 702 to form recesses 1502. In some examples, recesses 1502 extend through at least 30%, at least 40%, at least 50%, or at least 60% of an entire height (e.g., along the Z direction) of source or drain regions 702. In some examples, recesses 1502 extend through a portion of source or drain regions 702 that is above a plane coplanar with a bottommost surface of the lowest set of nanoribbons 802 or a bottommost surface of the second lowest set of nanoribbons 802. Note that a small portion of dielectric liner 1402 may remain on the bottom surface of source or drain regions 702 around the opening to recesses 1502. Recesses 1502 may also exhibit a tapering width, forming an elongated oval shape with a dome-shaped, pointed, or flat end.

FIGS. 16A and 16B depict cross-section views of the structure shown in FIGS. 15A and 15B, respectively, following the formation of backside contacts 1602 within cavities 1302 and 1502, according to some embodiments. Backside contacts 1602 may include any suitable conductive material, such as any of tungsten, ruthenium, molybdenum, or cobalt. Backside contacts 1602 will take the shape of cavities 1302 and 1502, and accordingly will have a generally tapered profile as they extend through source or drain regions 702. According to some embodiments, the portion of backside contacts 1602 that extend through source or drain regions 702 has an elongated oval shape with a domed, pointed, or flat end. This portion of backside contacts 1602 extends through at least 30%, at least 40%, at least 50%, or at least 60% of an entire height (e.g., along the Z direction) of source or drain regions 702. In some examples, this portion of backside contacts 1602 extends through a portion of source or drain regions 702 that is above a plane coplanar with a bottommost surface of the lowest set of nanoribbons 802 or a bottommost surface of the second lowest set of nanoribbons 802. Since sacrificial plugs 604 were self-aligned at the bottom of the source/drain trenches, backside contacts 1602 may respectively be self-aligned with their corresponding source or drain regions 702. For example, a center of backside contacts 1602 may be aligned within 1 nm of a center of source or drain regions 702.

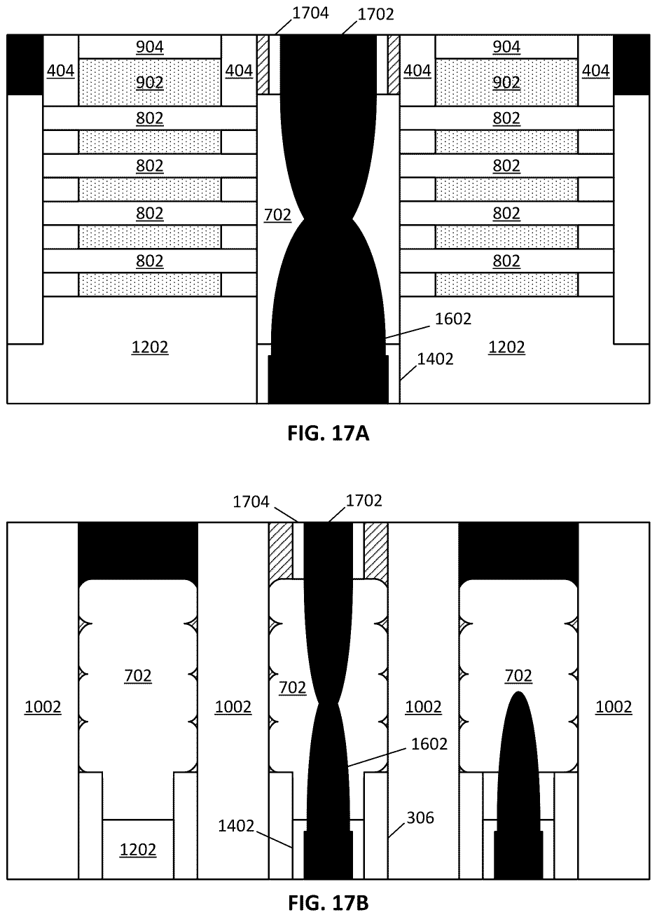

According to some embodiments, the lithographically patterned and etched backside contacts may be merged with frontside contacts to form a combined or merged contact through the entire height of a given source or drain region. FIGS. 17A and 17B depict cross-section views of another example structure having backside contact 1602 directly contacting a frontside contact 1702 within source or drain region 702. Frontside contact 1702 may be formed during frontside processing of the integrated circuit (e.g., prior to the removal of substrate 201). In some embodiments, another dielectric liner 1704 may be formed within a frontside cavity formed above source or drain region 702, followed by an RIE process to form a frontside recess into source or drain region, similar to the formation of recess 1502 through the backside of source or drain region 702. The frontside recess and frontside cavity may then be filled with one or more conductive materials to form frontside contact 1702. Frontside contact 1702 may include any of the conductive materials described above for backside contact 1602. In some examples, frontside contact 1702 includes the same conductive material as backside contact 1602.

The process described above for the formation of backside contact 1602 remains unchanged. Thus, according to some embodiments, the backside recess 1502 may expose a bottom surface of frontside contact 1702, such that backside contact 1602 is formed directly on a portion of frontside contact 1702 when filling backside cavities 1302 and 1502. According to some embodiments, a divot or recess may exist at a region where frontside contact 1702 contacts backside contact 1602. The divot or recess may be formed due to the tapered end profile of each of frontside contact 1702 and backside contact 1602.

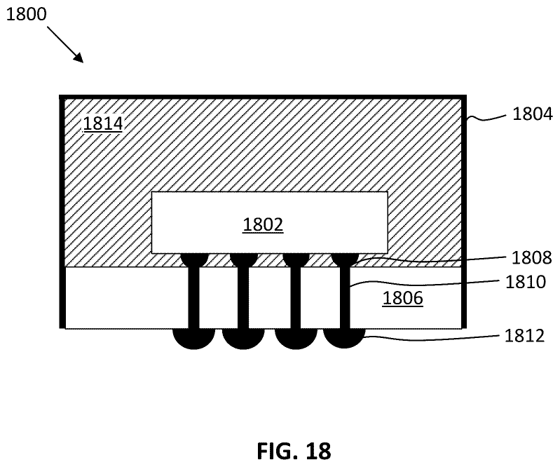

FIG. 18 illustrates an example embodiment of a chip package 1800, in accordance with an embodiment of the present disclosure. As can be seen, chip package 1800 includes one or more dies 1802. One or more dies 1802 may include at least one integrated circuit having semiconductor devices, such as any of the semiconductor devices disclosed herein. One or more dies 1802 may include any other circuitry used to interface with other devices formed on the dies, or other devices connected to chip package 1800, in some example configurations.

As can be further seen, chip package 1800 includes a housing 1804 that is bonded to a package substrate 1806. The housing 1804 may be any standard or proprietary housing, and may provide, for example, electromagnetic shielding and environmental protection for the components of chip package 1800. The one or more dies 1802 may be conductively coupled to a package substrate 1806 using connections 1808, which may be implemented with any number of standard or proprietary connection mechanisms, such as solder bumps, ball grid array (BGA), pins, or wire bonds, to name a few examples. Package substrate 1806 may be any standard or proprietary package substrate, but in some cases includes a dielectric material having conductive pathways (e.g., including conductive vias and lines) extending through the dielectric material between the faces of package substrate 1806, or between different locations on each face. In some embodiments, package substrate 1806 may have a thickness less than 1 millimeter (e.g., between 0.1 millimeters and 0.5 millimeters), although any number of package geometries can be used. Additional conductive contacts 1812 may be disposed at an opposite face of package substrate 1806 for conductively contacting, for instance, a printed circuit board (PCB). One or more vias 1810 extend through a thickness of package substrate 1806 to provide conductive pathways between one or more of connections 1808 to one or more of contacts 1812. Vias 1810 are illustrated as single straight columns through package substrate 1806 for ease of illustration, although other configurations can be used (e.g., damascene, dual damascene, through-silicon via, or an interconnect structure that meanders through the thickness of substrate 1806 to contact one or more intermediate locations therein). In still other embodiments, vias 1810 are fabricated by multiple smaller stacked vias, or are staggered at different locations across package substrate 1806. In the illustrated embodiment, contacts 1812 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1812, to inhibit shorting.

In some embodiments, a mold material 1814 may be disposed around the one or more dies 1802 included within housing 1804 (e.g., between dies 1802 and package substrate 1806 as an underfill material, as well as between dies 1802 and housing 1804 as an overfill material). Although the dimensions and qualities of the mold material 1814 can vary from one embodiment to the next, in some embodiments, a thickness of mold material 1814 is less than 1 millimeter. Example materials that may be used for mold material 1814 include epoxy mold materials, as suitable. In some cases, the mold material 1814 is thermally conductive, in addition to being electrically insulating.

### Methodology

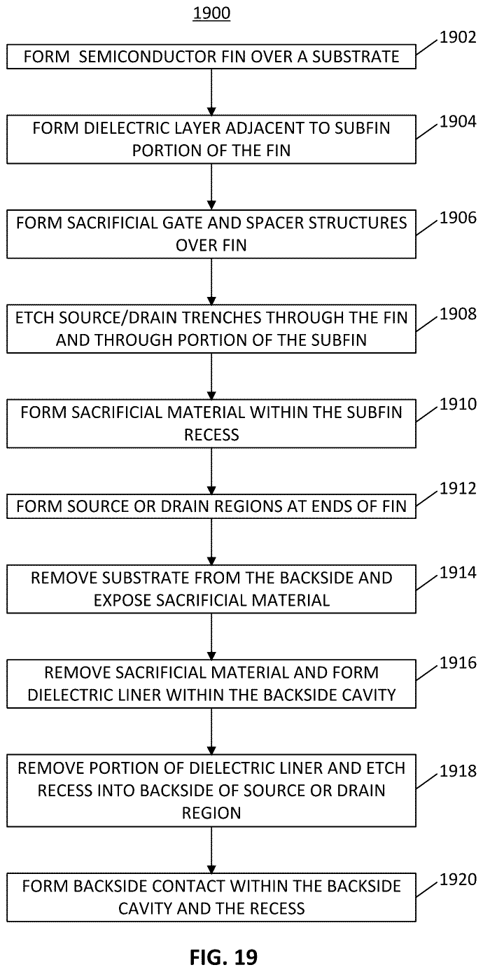

FIG. 19 is a flow chart of a method 1900 for forming at least a portion of an integrated circuit, according to an embodiment. Various operations of method 1900 may be illustrated in FIGS. 2A-16A and 2B-16B. However, the correlation of the various operations of method 1900 to the specific components illustrated in the aforementioned figures is not intended to imply any structural and/or use limitations. Rather, the aforementioned figures provide one example embodiment of method 1900. Other operations may be performed before, during, or after any of the operations of method 1900. For example, method 1900 does not explicitly describe various standard processes that are usually performed to form transistor structures. Some of the operations of method 1900 may be performed in a different order than the illustrated order.

Method 1900 begins with operation 1902 where a semiconductor fin is formed, according to some embodiments. The semiconductor material in the fin may be formed from a substrate such that the fin is an integral part of the substrate (e.g., etched from a bulk silicon substrate). Alternatively, the fin can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches. The fin may also include a cap structure that is used to define the location of the fin during, for example, an RIE process. The cap structure may be a dielectric material, such as silicon nitride.

Method 1900 continues with operation 1904 where a dielectric layer is formed around a subfin region of the fin. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide.

Method 1900 continues with operation 1906 where a sacrificial gate is formed over the fin. The sacrificial gate may be one gate of several sacrificial gates patterned using gate masking layers in strips that run orthogonally over the fins and parallel to one another (e.g., forming a cross-hatch pattern). The gate masking layer may be any suitable hard mask material, such as CHM or silicon nitride. The sacrificial gate itself may be formed from any suitable material that can be selectively removed at a later time without damaging the semiconductor material of the fin. In one example, the sacrificial gate includes polysilicon.

According to some embodiments, spacer structures are also formed on sidewalls of at least the sacrificial gate. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may be any suitable dielectric material, such as silicon nitride or silicon oxynitride.

Method 1900 continues with operation 1908 where source/drain trenches are etched through the fin and through at least a portion of the subfin region. Any exposed portions of the fin not covered by the sacrificial gate or spacer structures may be removed using any anisotropic etching process, such as reactive ion etching (RIE). According to some embodiments, the RIE process continues to etch beyond the height of the fin through the subfin region adjacent to the dielectric layer. The etched portion of the subfin region may be identified as a subfin recess.

Method 1900 continues with operation 1910 where a sacrificial material is formed within the subfin recess. The sacrificial material may be any suitable material that can be selectively removed (e.g., via isotropic etching) at a later time. In some examples, the sacrificial material is a dielectric material such as silicon nitride, but the sacrificial material may also be aluminum oxide or titanium nitride.

Method 1900 continues with operation 1912 where source or drain regions are formed at opposite ends of the fin. According to some embodiments, the source or drain regions are formed in the areas that had been previously occupied by the exposed fin between the spacer structures. The source or drain regions may be epitaxially grown from the exposed semiconductor material of the fins (or nanoribbons, nanowires or nanosheets, as the case may be) along the exterior walls of the spacer structures. In some example embodiments, the source or drain regions are NMOS source or drain regions (e.g., epitaxial silicon) or PMOS source or drain regions (e.g., epitaxial SiGe). A dielectric fill may be formed between and over the source or drain regions along a given source/drain trench. The dielectric fill may be any suitable dielectric material, such as silicon oxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth. The source or drain regions may be grown directly over the sacrificial material at the bottom of the source/drain trench.

Method 1900 continues with operation 1914 where the substrate is removed from the backside of the structure to expose the bottom surface of at least the sacrificial material. The substrate may be removed using any number of isotropic etching, polishing, or grinding operations. The subfin regions may also be removed at this time and replaced with any suitable dielectric material(s), such as silicon dioxide, to form a base dielectric structure.

Method 1900 continues with operation 1916 where the sacrificial material is removed from the backside and a dielectric liner is formed within the resulting backside cavity. Any suitable isotropic etching process may be used to selectively remove the sacrificial material. The cavity left behind from removing the sacrificial material exposes at least a bottom surface of the source or drain region directly above the cavity.

According to some embodiments, the dielectric liner is deposited using any suitable conformal deposition technique, such as chemical vapor deposition (CVD), plasma-enhanced chemical vapor deposition (PECVD), or atomic layer deposition (ALD). The dielectric layer may be any suitable dielectric material such as silicon nitride or titanium nitride and may have a thickness between about 1 nm and about 3 nm. The dielectric liner may be formed such that is covers the sidewalls of the backside cavity and the exposed bottom surface of the source or drain region.

Method 1900 continues with operation 1918 where a portion of the dielectric liner is removed during a directional etching process that continues into the source or drain region. According to some embodiments, a deep recess is etched using the directional etching process (e.g., RIE) that extends through at least 30%, at least 40%, at least 50%, or at least 60% of an entire height (e.g., along the Z direction) of the source or drain region. In some examples, the recess extends through a portion of the source or drain region that is above a plane coplanar with a bottommost surface of the lowest set of nanoribbons or a bottommost surface of the second lowest set of nanoribbons. A hard mask may be formed on the bottom of the base dielectric structure to protect the sidewalls of the dielectric liner during the etching process. Thus, in some examples, a small portion of the dielectric liner remains on the bottom surface of the source or drain regions around the opening of the recess. The recess may also exhibit a tapering width having an elongated oval shape with a dome-shaped, pointed, or flat end.

Method 1900 continues with operation 1920 where a backside contact is formed within the backside cavity and within the recess into the source or drain region. According to some embodiments, the backside contact is formed directly on exposed surface(s) of the source or drain region in the recess. The backside contact may include any suitable conductive material, such as cobalt, ruthenium, molybdenum, or tungsten. According to some embodiments, the backside contact is part of a backside interconnect structure to connect the source or drain region to a power or ground rail. Due to the geometry of the recess, the backside contact may extend into the source or drain region, such as at least 30%, 40%, 50%, or 60% of an entire height of the source or drain region. Note that if a frontside contact was previously formed that also extended into the source or drain region, then the backside contact may be formed on a portion of the frontside contact within the source or drain region to yield a combined or merged contact structure that extends through the entire height of the source or drain region.

As noted above, some of the operations may be performed in a different order to still yield the same or similar final structure. For example, the semiconductor subfin regions may remain throughout operations 1916, 1918, and 1920, and are removed and replaced with the base dielectric structure following the formation of the backside contact.

### Example System

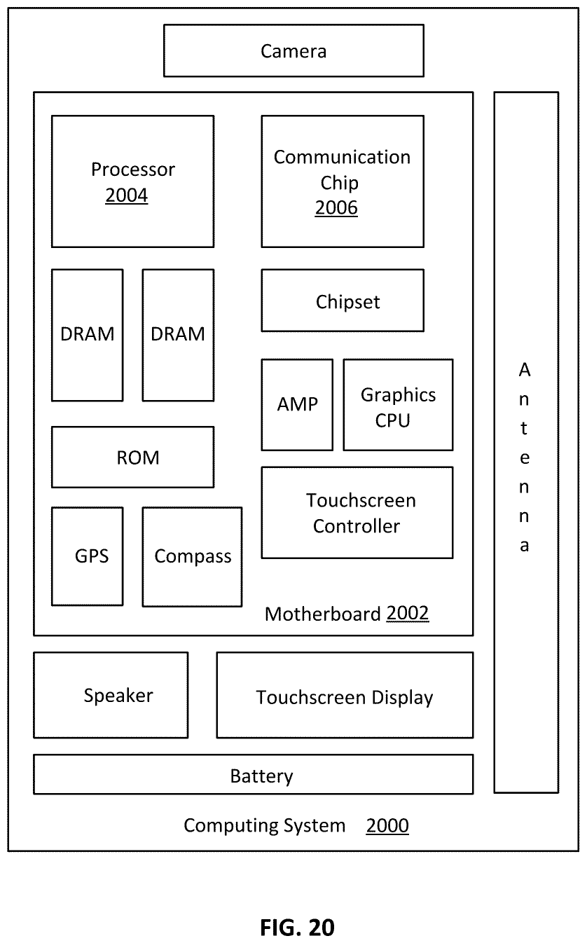

FIG. 20 is an example computing system implemented with one or more of the integrated circuit structures as disclosed herein, in accordance with some embodiments of the present disclosure. As can be seen, the computing system 2000 houses a motherboard 2002. The motherboard 2002 may include a number of components, including, but not limited to, a processor 2004 and at least one communication chip 2006, each of which can be physically and electrically coupled to the motherboard 2002, or otherwise integrated therein. As will be appreciated, the motherboard 2002 may be, for example, any printed circuit board (PCB), whether a main board, a daughterboard mounted on a main board, or the only board of system 2000, etc.

Depending on its applications, computing system 2000 may include one or more other components that may or may not be physically and electrically coupled to the motherboard 2002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 2000 may include one or more integrated circuit structures or devices configured in accordance with an example embodiment (e.g., a module including one or more semiconductor devices that include backside contacts extending into the source or drain regions, as variously provided herein). In some embodiments, multiple functions can be integrated into one or more chips (e.g., for instance, note that the communication chip 2006 can be part of or otherwise integrated into the processor 2004).

The communication chip 2006 enables wireless communications for the transfer of data to and from the computing system 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2000 may include a plurality of communication chips 2006. For instance, a first communication chip 2006 may be dedicated to shorter range wireless communications such as Wi-Fi and Bluetooth and a second communication chip 2006 may be dedicated to longer range wireless communications such as GPS, EDGE, GPRS, CDMA, WiMAX, LTE, Ev-DO, and others.

The processor 2004 of the computing system 2000 includes an integrated circuit die packaged within the processor 2004. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 2006 also may include an integrated circuit die packaged within the communication chip 2006. In accordance with some such example embodiments, the integrated circuit die of the communication chip includes one or more semiconductor devices as variously described herein. As will be appreciated in light of this disclosure, note that multi-standard wireless capability may be integrated directly into the processor 2004 (e.g., where functionality of any chips 2006 is integrated into processor 2004, rather than having separate communication chips). Further note that processor 2004 may be a chip set having such wireless capability. In short, any number of processor 2004 and/or communication chips 2006 can be used. Likewise, any one chip or chip set can have multiple functions integrated therein.

In various implementations, the computing system 2000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 2000 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a semiconductor device having a semiconductor region extending in a first direction from a source or drain region and a gate structure extending in a second direction over the semiconductor region, a dielectric layer beneath the gate structure, a backside conductive contact extending through the dielectric layer and through at least a portion of a total height of the source or drain region, and a dielectric liner on sidewall surfaces of the backside conductive contact. The dielectric liner is between the backside conductive contact and the dielectric layer, and at least a portion of the dielectric liner contacts a bottom surface of the source or drain region.

Example 2 includes the integrated circuit of Example 1, wherein the semiconductor region comprises one or more semiconductor nanoribbons.

Example 3 includes the integrated circuit of Example 2, wherein the one or more semiconductor nanoribbons comprise germanium, silicon, or any combination thereof.

Example 4 includes the integrated circuit of Example 2 or 3, wherein the backside conductive contact extends above a plane coplanar with a bottommost nanoribbon of the one or more semiconductor nanoribbons.

Example 5 includes the integrated circuit of any one of Examples 1-4, further comprising a frontside conductive contact extending through at least a portion of the total height of the source or drain region.

Example 6 includes the integrated circuit of Example 5, wherein the frontside conductive contact contacts the backside conductive contact within the source or drain region.

Example 7 includes the integrated circuit of Example 5 or 6, wherein the dielectric liner is a first dielectric liner and the integrated circuit further comprises a second dielectric liner on sidewall surfaces of the frontside conductive contact, wherein at least a portion of the second dielectric liner contacts a top surface of the source or drain region.

Example 8 includes the integrated circuit of any one of Examples 5-7, wherein the backside conductive contact has a tapering width as it extends towards a top surface of the source or drain region and the frontside conductive contact has a tapering width as it extends towards the bottom surface of the source or drain region.

Example 9 includes the integrated circuit of any one of Examples 1-8, wherein the dielectric liner comprises silicon and nitrogen or titanium and oxygen.

Example 10 includes the integrated circuit of any one of Examples 1-9, further comprising a backside conductive layer that contacts a bottom surface of the backside conductive contact.

Example 11 is a die that includes the integrated circuit of any one of Examples 1-10.

Example 12 is an electronic device that includes a chip package having one or more dies. At least one of the one or more dies includes a semiconductor region extending in a first direction from a source or drain region, a gate structure extending in a second direction over the semiconductor region, a dielectric layer beneath the gate structure, a backside conductive contact extending through the dielectric layer and through at least a portion of a total height of the source or drain region, and a dielectric liner on sidewall surfaces of the backside conductive contact. The dielectric liner is between the backside conductive contact and the dielectric layer along the first direction. At least a portion of the dielectric liner contacts a bottom surface of the source or drain region.

Example 13 includes the electronic device of Example 12, wherein the semiconductor region comprises one or more semiconductor nanoribbons.

Example 14 includes the electronic device of Example 13, wherein the one or more semiconductor nanoribbons comprise germanium, silicon, or any combination thereof.

Example 15 includes the electronic device of Example 13 or 14, wherein the backside conductive contact extends above a plane coplanar with a bottommost nanoribbon of the one or more semiconductor nanoribbons.

Example 16 includes the electronic device of any one of Examples 12-15, wherein the at least one of the one or more dies further comprises a frontside conductive contact extending through at least a portion of the total height of the source or drain region.

Example 17 includes the electronic device of Example 16, wherein the frontside conductive contact contacts the backside conductive contact within the source or drain region.

Example 18 includes the electronic device of Example 16 or 17, wherein the dielectric liner is a first dielectric liner and the at least one of the one or more dies further comprises a second dielectric liner on sidewall surfaces of the frontside conductive contact, wherein at least a portion of the second dielectric liner contacts a top surface of the source or drain region.

Example 19 includes the electronic device of any one of Examples 16-18, wherein the backside conductive contact has a tapering width as it extends towards a top surface of the source or drain region and the frontside conductive contact has a tapering width as it extends towards the bottom surface of the source or drain region.

Example 20 includes the electronic device of any one of Examples 12-19, wherein the dielectric liner comprises silicon and nitrogen, or titanium and oxygen.

Example 21 includes the electronic device of any one of Examples 12-20, further comprising a backside conductive layer that contacts a bottom surface of the backside conductive contact.

Example 22 includes the electronic device of any one of Examples 12-21, wherein the at least one of the one or more dies further comprises a printed circuit board, wherein the chip package is attached to the printed circuit board.

Example 23 is a method of forming an integrated circuit. The method includes: forming a fin comprising semiconductor material, the fin extending above a substrate; forming a dielectric layer adjacent to a subfin of the fin; forming a sacrificial gate and spacer structures over the fin; removing portions of the fin not covered by the sacrificial gates and spacer structures; removing a subfin region of the fin to form a subfin cavity; forming a sacrificial plug within the subfin cavity; forming a source or drain region at exposed ends of the semiconductor material and over the sacrificial plug; removing a portion of the substrate from a backside of the integrated circuit to expose a bottom surface of the subfin and a bottom surface of the sacrificial material; removing the sacrificial plug from the backside to form a backside cavity; forming a dielectric liner within the backside cavity; removing a portion of the dielectric liner on a bottom surface of the source or drain region; etching a recess into the exposed bottom surface of the source or drain region; and forming a conductive contact within both the backside cavity and within the recess.

Example 24 includes the method of Example 23, wherein etching the recess comprises etching the recess using reactive ion etching (RIE).

Example 25 includes the method of Example 23 or 24, wherein the sacrificial plug comprises titanium and nitrogen or silicon and nitrogen.

Example 26 includes the method of any one of Examples 23-25, further comprising removing the subfin from the backside and replacing the subfin with a dielectric layer.

Example 27 includes the method of any one of Examples 23-26, wherein the dielectric liner comprises silicon and nitrogen or titanium and oxygen.

Example 28 includes the method of any one of Examples 23-27, wherein the recess is a first recess and the conductive contact is a first conductive contact. The method further comprises: etching a second recess through a top surface of the source or drain region; and forming a second conductive contact within the second recess. Etching the first recess comprises etching the first recess into the exposed bottom surface of the source or drain region and exposing at least a portion of the second conductive contact.

Example 29 is an integrated circuit that includes a semiconductor device having a semiconductor region extending in a first direction from a source or drain region and a gate structure extending in a second direction over the semiconductor region, a dielectric layer beneath the gate structure, and a conductive contact extending through the dielectric layer and through an entire height of the source or drain region. The conductive contact has a first section having a tapering width from a bottom surface of the source or drain region to a top of the first section, and a second section having a tapering width from a top surface of the source or drain region to the bottom of the second section. The conductive contact has a smallest width at an interface between the first section and the second section of the conductive contact.

Example 30 includes the integrated circuit of Example 29, further comprising a dielectric liner on sidewalls of the conducive contact between the conductive contact and the dielectric layer.

Example 31 includes the integrated circuit of Example 30, wherein a portion of the dielectric liner contacts a bottom surface of the source or drain region.

Example 32 includes the integrated circuit of any one of Examples 29-31, wherein a width of the first section of the conductive contact at the bottom surface of the source or drain region is within 2 nm of a width of the second section of the conductive contact at the top surface of the source or drain region.

Example 33 includes the integrated circuit of Example 32, wherein the smallest width at the interface between the first section and the second section of the conductive contact is at least 5 nm smaller than the width of the first section of the conductive contact at the bottom surface of the source or drain region and the width of the second section of the conductive contact at the top surface of the source or drain region.

Example 34 includes the integrated circuit of any one of Examples 29-33, wherein the semiconductor region comprises one or more semiconductor nanoribbons.

Example 35 includes the integrated circuit of Example 34, wherein the one or more semiconductor nanoribbons comprise germanium, silicon, or any combination thereof.

Example 36 includes the integrated circuit of any one of Examples 29-35, further comprising: a backside conductive layer that contacts a bottom surface of the conductive contact; and a frontside conductive layer that contacts a top surface of the conductive contact.

Example 37 is a die that includes the integrated circuit of any one of Examples 29-36.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having a semiconductor region extending in a first direction from a source or drain region and a gate structure extending in a second direction over the semiconductor region;
a dielectric layer beneath the gate structure;
a backside conductive contact extending through the dielectric layer and through at least a portion of a total height of the source or drain region; and
a dielectric liner on sidewall surfaces of the backside conductive contact, wherein the dielectric liner is between the backside conductive contact and the dielectric layer, and wherein at least a portion of the dielectric liner contacts a bottom surface of the source or drain region.

2. The integrated circuit of claim 1, wherein the semiconductor region comprises one or more semiconductor nanoribbons.

3. The integrated circuit of claim 2, wherein the backside conductive contact extends above a plane coplanar with a bottommost nanoribbon of the one or more semiconductor nanoribbons.

4. The integrated circuit of claim 1, further comprising a frontside conductive contact extending through at least a portion of the total height of the source or drain region.

5. The integrated circuit of claim 4, wherein the frontside conductive contact contacts the backside conductive contact within the source or drain region.

6. The integrated circuit of claim 4, wherein the backside conductive contact has a tapering width as it extends towards a top surface of the source or drain region and the frontside conductive contact has a tapering width as it extends towards the bottom surface of the source or drain region.

7. The integrated circuit of claim 1, further comprising a backside conductive layer that contacts a bottom surface of the backside conductive contact.

8. A die comprising the integrated circuit of claim 1.

9. An electronic device, comprising:
a chip package comprising one or more dies, at least one of the one or more dies comprising
a semiconductor region extending in a first direction from a source or drain region;
a gate structure extending in a second direction over the semiconductor region;
a dielectric layer beneath the gate structure;
a backside conductive contact extending through the dielectric layer and through at least a portion of a total height of the source or drain region; and
a dielectric liner on sidewall surfaces of the backside conductive contact, wherein the dielectric liner is between the backside conductive contact and the dielectric layer along the first direction, and wherein at least a portion of the dielectric liner contacts a bottom surface of the source or drain region.

10. The electronic device of claim 9, wherein the semiconductor region comprises one or more semiconductor nanoribbons, and the backside conductive contact extends above a plane coplanar with a bottommost nanoribbon of the one or more semiconductor nanoribbons.

11. The electronic device of claim 9, wherein the at least one of the one or more dies further comprises a frontside conductive contact extending through at least a portion of the total height of the source or drain region.

12. The electronic device of claim 11, wherein the frontside conductive contact contacts the backside conductive contact within the source or drain region.

13. The electronic device of claim 11, wherein the backside conductive contact has a tapering width as it extends towards a top surface of the source or drain region and the frontside conductive contact has a tapering width as it extends towards the bottom surface of the source or drain region.

14. An integrated circuit comprising:
a semiconductor device having a semiconductor region extending in a first direction from a source or drain region and a gate structure extending in a second direction over the semiconductor region;
a dielectric layer beneath the gate structure; and
a conductive contact extending through the dielectric layer and through an entire height of the source or drain region, wherein the conductive contact comprises a first section having a tapering width from a bottom surface of the source or drain region to a top of the first section, and a second section having a tapering width from a top surface of the source or drain region to the bottom of the second section, wherein the conductive contact has a smallest width at an interface between the first section and the second section of the conductive contact.

15. The integrated circuit of claim 14, further comprising a dielectric liner on sidewalls of the conducive contact between the conductive contact and the dielectric layer.

16. The integrated circuit of claim 15, wherein a portion of the dielectric liner contacts a bottom surface of the source or drain region.

17. The integrated circuit of claim 14, wherein a width of the first section of the conductive contact at the bottom surface of the source or drain region is within 2 nm of a width of the second section of the conductive contact at the top surface of the source or drain region.

18. The integrated circuit of claim 17, wherein the smallest width at the interface between the first section and the second section of the conductive contact is at least 5 nm smaller than the width of the first section of the conductive contact at the bottom surface of the source or drain region and the width of the second section of the conductive contact at the top surface of the source or drain region.

19. The integrated circuit of claim 14, wherein the semiconductor region comprises one or more semiconductor nanoribbons.

20. The integrated circuit of claim 14, further comprising:
a backside conductive layer that contacts a bottom surface of the conductive contact; and
a frontside conductive layer that contacts a top surface of the conductive contact.
